(19) United States
(12) Patent Application Publication
(10) Pub. No.: US 2025/0056946 A1
(43) Pub. Date: Feb. 13, 2025

(54) DISPLAY DEVICE

(71) Applicant: LG Display Co., Ltd., Seoul (KR)

(72) Inventors: Hye Sun JUNG, Paju-si (KR); Bung Goo KIM, Paju-si (KR); Hyoung Ho AHN, Paju-si (KR); Hee Won LEE, Paju-si (KR); Jun Young JO, Paju-si (KR); Sang Hak SHIN, Paju-si (KR); Jae Kwang LEE, Paju-si (KR); Hyoung Sun PARK, Paju-si (KR); Pyung Ho CHOI, Paju-si (KR); Tae Yoon KIM, Paju-si (KR)

(21) Appl. No.: 18/794,897

(22) Filed: Aug. 5, 2024

(30) Foreign Application Priority Data
Aug. 7, 2023 (KR) 10-2023-0103083

(51) Int. Cl. H01L 33/62; H01L 25/075; H01L 33/58

(52) U.S. Cl. CPC H01L 33/62; H01L 25/0753; H01L 33/58

(57) ABSTRACT

An embodiment of the present specification discloses a display device including a display panel including a display area and a non-display area adjacent to the display area and a metal dam disposed in the non-display area to surround at least three surfaces of the display panel. The display panel includes a substrate, a pixel driving circuit disposed on the substrate, and a light emitting element driven by the pixel driving circuit, the metal dam may be spaced a selected distance from an edge of the display panel, the metal dam may be formed of a plurality of metal layers connected through at least one hole, and the metal dam may include a first metal dam, a second metal dam, and a third metal dam that are disposed in the non-display area while surrounding at least three surfaces of the display area.

### CROSS-REFERENCE TO RELATED APPLICATION

This application claims priority to and the benefit of Korean Patent Application No. 2023-0103083, filed on Aug. 7, 2023, the disclosure of which is incorporated herein by reference in its entirety.

### BACKGROUND

### Technical Field

Embodiments relate to a display device using an inorganic light emitting diode as a light source.

### Description of the Related Art

Electroluminescent display devices include organic light emitting diode (hereinafter referred to as “OLED”) display devices, in which OLEDs are disposed, and inorganic light emitting diode display devices (hereinafter referred to as “LED display devices”) in which inorganic light emitting diodes (hereinafter referred to as “LEDs”) are disposed.

Since electroluminescent display devices display images using self-luminous elements, the electroluminescent displays do not require a separate light source, such as a backlight unit, and thus can be implemented in thin and various forms.

OLED display devices require a design for preventing the permeation of oxygen and moisture because an oxidation phenomenon between an organic light emitting layer and an electrode may occur due to the permeation of moisture and oxygen.

Recently, as an example of LED display devices, a micro LED display device in which micro LEDs are disposed in pixels has been attracting attention as a next-generation display device. A micro LED may be an inorganic LED with a size of 100 μm or less. Micro LEDs may be manufactured by a separate semiconductor process, transferred to pixels located on a display panel substrate of the display device, and disposed in sub-pixels for each color.

Each micro LED may be connected to an anode and a cathode to receive power.

### BRIEF SUMMARY

Embodiments are directed to providing a display device in which phenomena of cracks occurring on an organic layer due to moisture and heat permeating through an edge area of a display panel and metal layer delamination can be prevented.

The technical benefits of the present disclosure is not limited to the above-described benefits, and other benefits that are not mentioned will be able to be clearly understood by those skilled in the art from the following description.

A display device according to an embodiment of the present disclosure includes a display panel including a display area and a non-display area surrounding the display area, and a metal dam disposed in the non-display area to surround at least three surfaces of the display panel, wherein the display panel includes a substrate, a pixel driving circuit disposed on the substrate, and a light emitting element driven by the pixel driving circuit.

According to the present disclosure, parasitic capacitance generated in a region where the cathode electrode and the signal wiring overlap may be reduced, and an increase in resistance of the cathode electrode may be improved, thereby enabling low power driving.

The effects of the present disclosure are not limited to the above-mentioned effects, and other effects not mentioned will be clearly understood by those skilled in the art from the description of the claims.

### BRIEF DESCRIPTION OF THE SEVERAL VIEWS OF THE DRAWINGS

FIG. 1 is a view showing a display device according to one embodiment of the present specification.

FIG. 2 is an enlarged view of area A in FIG. 1.

FIG. 3 is a view showing a partial area of a pixel.

FIG. 4 is a cross-sectional view along line I-I′ in FIG. 3.

FIG. 5 is a cross-sectional view along line II-II′ in FIG. 3.

FIG. 6 is a cross-sectional view along line III-III′ in FIG. 3.

FIG. 7 is a cross-sectional view showing one example in which a main light emitting element and a sub light emitting element are electrically connected to a pixel driving circuit.

FIG. 8 is a view showing a display device according to another embodiment of the present specification.

FIG. 9 is a cross-sectional view along line IV-IV′ in FIG. 8.

FIG. 10 is a view showing a state in which stress is concentrated on a second electrode disposed in a through-hole.

FIG. 11 is a view showing a first modified example of the display device of FIG. 8.

FIG. 12 is a view showing a second modified example of the display device of FIG. 8.

FIGS. 13A to 13F are views showing a method of manufacturing the display device according to one embodiment of the present specification.

FIG. 14 is a view showing a modified example of the second electrode.

FIG. 15 is a cross-sectional view along line V-V′ in FIG. 14.

FIG. 16 is a cross-sectional view along line VI-VI′ in FIG. 1.

FIG. 17 is a plan view showing the display device according to one embodiment of the present disclosure.

FIGS. 18A, 18B, and 18C are cross-sectional views along line VII-VII′ in FIG. 17.

### DETAILED DESCRIPTION

Advantages and features of the present disclosure and methods of achieving them will become clear with reference to embodiments described below in detail in conjunction with the accompanying drawings. The present disclosure is not limited to the embodiments disclosed below but can be implemented in various different forms, these embodiments are merely provided to make the disclosure of the present disclosure complete and fully inform those skilled in the art to which the present disclosure pertains of the scope of the present disclosure, and the present disclosure is only defined by the scope of the appended claims.

Since shapes, sizes, dimensions (e.g., length, width, height, thickness, radius, diameter, area, etc.), ratios, angles, numbers, and the like disclosed in the drawings for describing the embodiments of the present disclosure are illustrative, the present disclosure is not limited to the shown items.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference number indicates the same components throughout the specification. In addition, in describing the present disclosure, when it is determined that the detailed description of a related known technology may unnecessarily obscure the gist of the present disclosure, detailed description thereof will be omitted.

When the terms “comprise,” “include,” “have,” and “consist of” described in the present specification are used, other parts may be added unless “only” is used. When a component is expressed in the singular, it can be construed as a plurality of components unless specifically stated otherwise.

In construing a component, the component is construed as including the margin of error even when there is no separate explicit description.

When the position relationship and interconnection relationship between two components, such as “on,” “above,” “under,” “next to,” “connected or coupled,” “crossing or intersecting,” or the like described, one or more other components may be interposed between the components unless the term “immediately” or “directly” is described.

When the temporal relationship is described using the term “after,” “subsequently,” “then,” “before,” or the like, it may include a non-consecutive case unless the term “immediately” or “directly” is used.

To distinguish components, “first,” “second,” and the like may be used in front of the names of the components, but functions or structures thereof are not limited by the ordinal numbers or component names. For convenience of description, the ordinal number of the names of the same components may be different between embodiments.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

The following embodiments may be partially or fully coupled or combined, and various technological interworking and driving are possible. The embodiments may be implemented independently of each other and implemented together in the associated relationship.

Hereinafter, various embodiments of the present disclosure will be described in detail with reference to the accompanying drawings.

A display device according to one embodiment of the present specification includes a display panel including a display area where images are displayed or a screen is displayed, and a pixel driving circuit for driving pixels of the display panel. The display area includes a pixel area where the pixels are disposed. The pixel area includes a plurality of light emitting areas. A light emitting element is disposed in each of the light emitting areas. The pixel driving circuit may be embedded in the display panel.

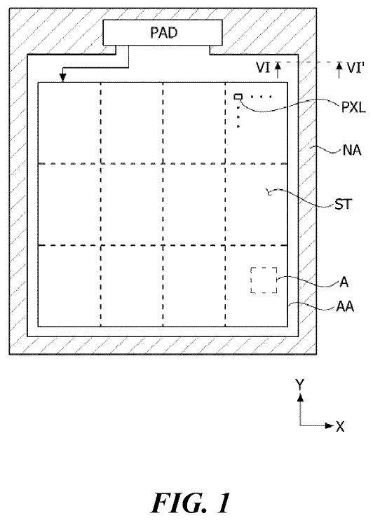

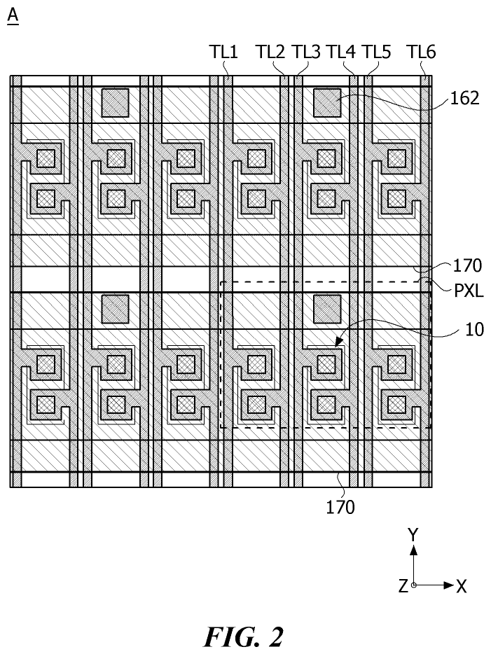

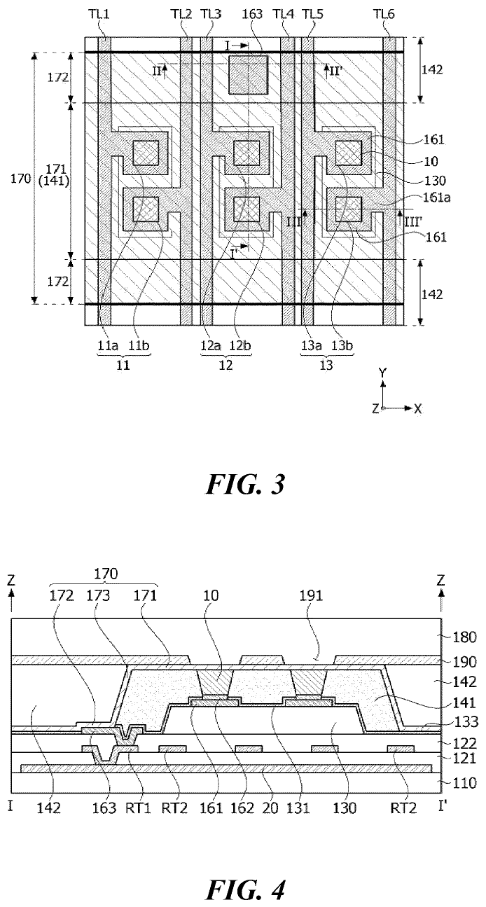

FIG. 1 is a view showing a display device according to one embodiment of the present specification. FIG. 2 is an enlarged view of area A in FIG. 1. FIG. 3 is a view showing a partial area of a pixel.

Referring to FIGS. 1 and 2, a display device 100 according to the embodiment of the present specification includes a display panel that visually displays an input image. The display panel may include a display area AA where an image is displayed and a non-display area NA where the image is not displayed. Various lines and driving circuits may be mounted in the non-display area NA, and a pad part PAD to which integrated circuits, printed circuits, and the like are connected.

A plurality of light emitting elements 10 disposed in the display area AA and forming a pixel PXL may be micro-sized inorganic light emitting elements. The inorganic light emitting element may be grown on a silicon wafer and then attached to the display panel through a transfer process.

The transfer process of the light emitting element 10 may be performed for each pre-divided area. Although FIG. 1 shows that the display area AA is divided into nine transfer areas ST, the sizes or number of divisions of the transfer areas is not limited thereto. The transfer process may be performed sequentially or simultaneously on the first to ninth transfer areas ST. The blue light emitting element 10, the green light emitting element 10, and the red light emitting element 10 may each be sequentially transferred to the transfer areas ST.

A data driving circuit or gate driving circuit may be disposed in the non-display area NA, and lines through which control signals for controlling the driving circuits are supplied may be disposed. Here, the control signals may include various timing signals including a clock signal, an input data enable signal, and synchronization signals and may be received through the pad part PAD.

The pixels PXL may be driven by the pixel driving circuit. The pixel driving circuit may drive a plurality of pixels by receiving a driving voltage, image signals (digital signals), synchronization signals synchronized with the image signals, and the like and outputting an anode voltage and a cathode voltage of the light emitting element 10. The driving voltage may be a high potential voltage EVDD. The cathode voltage may be a low potential voltage EVSS commonly applied to the pixels. The anode voltage may be a voltage corresponding to a pixel data value of the image signal. The pixel driving circuit may be disposed in the non-display area NA or under the display area AA.

Each of the pixels PXL may include a plurality of sub-pixels each having a different color. For example, the plurality of pixels may include a red sub-pixel in which the light emitting element 10 for emitting light having a red wavelength is disposed, a green sub-pixel in which the light emitting element 10 for emitting light having a green wavelength is disposed, and a blue sub-pixel in which the light emitting element 10 for emitting light having a blue wavelength is disposed. The plurality of pixels may further include white pixels.

Referring to FIGS. 2 and 3, the plurality of pixels PXL may be consecutively disposed in a first direction (X-axis direction) and a second direction (Y-axis direction). A plurality of sub-pixels of the same color may be disposed in the pixel of the display area AA. For example, each of the plurality of pixels may include a first red sub-pixel in which a 1-1 light emitting element 11a for emitting light having the red wavelength, a second red sub-pixel in which a 1-2 light emitting element 11b for emitting light having the red wavelength, a first green sub-pixel in which a 2-1 light emitting element 12a for emitting light having the green wavelength, a second green sub-pixel in which a 2-2 light emitting element 12b for emitting light having the green wavelength, a first blue sub-pixel in which a 3-1 light emitting element 13a for emitting light having the blue wavelength, and a second blue sub-pixel in which a 3-2 light emitting element 13b for emitting light having the blue wavelength. The 1-1 light emitting element 11a, the 2-1 light emitting element 12a, and the 3-1 light emitting element 13a may be construed as main light emitting elements. The 1-2 light emitting element 11b, the 2-2 light emitting element 12b, and the 3-2 light emitting element 13b may be construed as sub light emitting elements.

One sub-pixel includes one or more light emitting elements, and when one light emitting element fails, the brightness of the sub-pixel may be adjusted by increasing the brightness of the remaining light emitting elements. However, the present disclosure is not necessarily limited thereto, and one sub-pixel may include only one light emitting element.

A plurality of first electrodes 161 may each be disposed under the light emitting element 10 and may be selectively connected to a plurality of signal lines TL1 to TL6 through an extension 161a. The high potential voltage may be applied to the pixel driving circuit through the signal lines TL to TL6. The signal lines TL to TL6 and the first electrode 161 may be formed as an integrated electrode pattern during an electrode patterning process.

As an example, the first signal line TL1 may be connected to an anode of the first red sub-pixel, and the second signal line TL2 may be connected to an anode of the second red sub-pixel. The third signal line TL3 may be connected to an anode of the first green sub-pixel, and the fourth signal line TL4 may be connected to an anode of the second green sub-pixel. The fifth signal line TL5 may be connected to an anode of the first blue sub-pixel, and the sixth signal line TL6 may be connected to an anode of the second blue sub-pixel. When one sub-pixel includes only one light emitting element, the number of signal lines TL may be reduced by half.

The second electrode 170 may be a cathode electrode that is disposed in each row and applies the cathode voltage to the light emitting elements 10 consecutively disposed in the first direction (X-axis direction). The plurality of second electrodes 170 may be disposed to be spaced apart from each other in the second direction (Y-axis direction). The plurality of second electrodes 170 may be connected to the cathode voltage through contact electrodes 163. The plurality of second electrodes 170 may each be electrically connected to the contact electrode 163. However, the present disclosure is not limited thereto, and the second electrode 170 is not divided into a plurality of second electrodes and may be formed as one electrode layer serving as a common electrode.

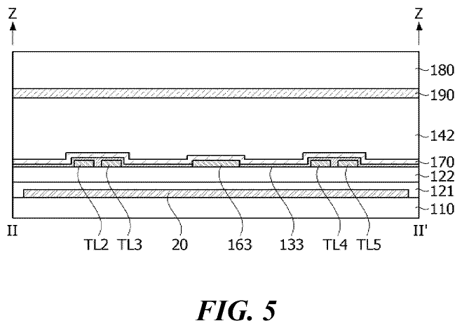

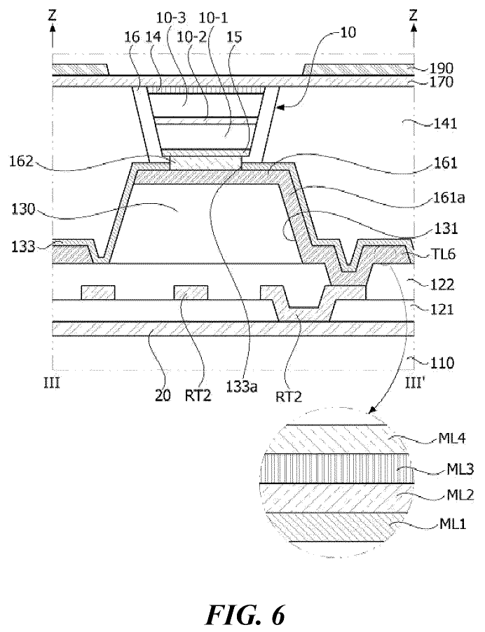

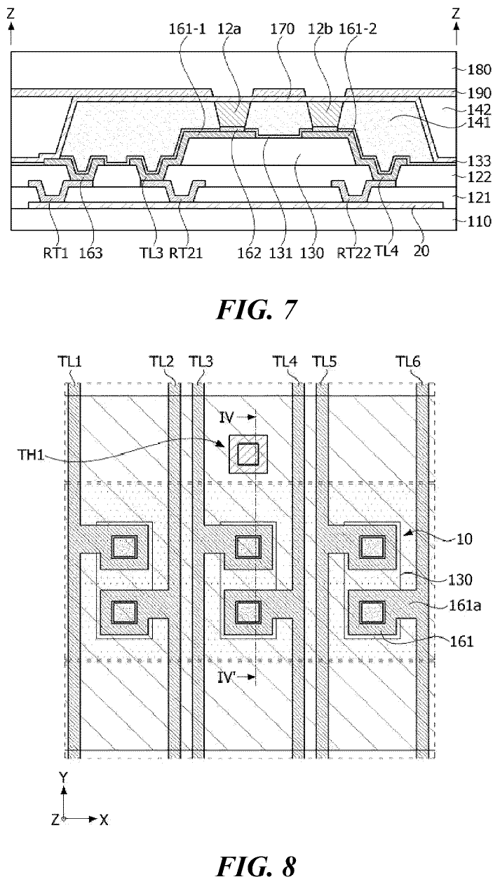

FIG. 4 is a cross-sectional view along line I-I′ in FIG. 3. FIG. 5 is a cross-sectional view along line II-II′ in FIG. 3. FIG. 6 is a cross-sectional view along line III-III′ in FIG. 3. FIG. 7 is a cross-sectional view showing an example in which two light emitting elements are connected to a pixel driving circuit.

Referring to FIGS. 3 to 5, the display device according to the embodiment includes a plurality of first electrodes 161 and a contact electrode 163 that are disposed on a substrate 110, a plurality of light emitting elements 10 disposed on the plurality of first electrodes 161, a first optical layer 141 disposed between the plurality of light emitting elements 10, and a second electrode 170 disposed on the plurality of light emitting elements 10.

The substrate 110 may be made of flexible plastic. For example, the substrate 110 may be formed as a single layer or multiple layers made of a material selected from polyimide, polyethylene terephthalate, polyethylene naphthalate, polycarbonate, polyethersulfone, polyarylate, polysulfone, and cyclic-olefin copolymer may be manufactured as a single-layer or multilayered substrate, but is not limited thereto. For example, the substrate 110 may be a ceramic substrate or a glass substrate.

A pixel driving circuit 20 may be disposed in the display area AA on the substrate 110. The pixel driving circuit 20 may include a plurality of thin film transistors using an amorphous silicon semiconductor, a polycrystalline silicon semiconductor, or an oxide semiconductor.

The pixel driving circuit 20 may include at least one driving thin film transistor, at least one switching thin film transistor, and at least one storage capacitor. When the pixel driving circuit 20 includes a plurality of thin film transistors, the pixel driving circuit 20 may be formed on the substrate 110 by a process of manufacturing a thin film transistor (TFT). In an embodiment, the connect of the pixel driving circuit 20 may be generally referred to as the plurality of thin film transistors electrically connected to the light emitting element 10.

The pixel driving circuit 20 may be a driving driver manufactured on the single crystal semiconductor substrate 110 using a process of manufacturing a metal-oxide-silicon field effect transistor (MOSFET). The driving driver may include a plurality of pixel driving circuits and drive a plurality of sub-pixels. When the pixel driving circuit 20 is implemented as the driving driver, after an adhesive layer is disposed on the substrate 110, the driving driver may be mounted on the adhesive layer by the transfer process.

A buffer layer 121 for covering the pixel driving circuit 20 may be disposed on the substrate 110. The buffer layer 121 may be made of an organic insulating material, such as photosensitive photo acryl or photosensitive polyimide, but is not limited thereto.

The buffer layer 121 may be provided as multiple layers formed by stacking inorganic insulating materials, such as silicon nitride (SiNₓ) or silicon oxide (SiO₂), or multiple layers formed by stacking an organic insulating material and an inorganic insulating material.

An insulating layer 122 may be disposed on the buffer layer 121. The insulating layer 122 may be made of an organic insulating material, such as photosensitive photo acryl or photosensitive polyimide, but is not limited thereto. Connection lines RT1 and RT2 may be disposed on the buffer layer 121. The connection lines RT1 and RT2 may be connected to the corresponding signal lines TL1 to TL6 or connected to the signal lines TL1 to TL6. The connection lines RT1 and RT2 may include a plurality of line patterns disposed on different layers with one or more insulating layers interposed therebetween. Line patterns disposed on different layers may be electrically connected through contact holes passing through the insulating layer.

A plurality of bank patterns 130 may be disposed on the insulating layer 122. At least one light emitting element 10 may be disposed on each bank pattern 130. For example, the first light emitting element 11 may be disposed on the first bank pattern 130, the second light emitting element 12 may be disposed on the second bank pattern 130, and the third light emitting element may be disposed on the third bank pattern 130.

The bank pattern 130 may be made of an organic insulating material, such as photosensitive photo acryl or photosensitive polyimide, but is not limited thereto. The bank pattern 130 may guide an attachment position of the light emitting element 10 in the transfer process of the light emitting element 10. The bank pattern 130 may be omitted.

A solder pattern 162 may be disposed on the first electrode 161. The solder pattern 162 may be made of indium (In), tin (Sn), or an alloy thereof, but is not limited thereto.

A plurality of light emitting elements 10 may each be mounted on the solder pattern 162. One pixel may include light emitting elements 10 of three colors. The first light emitting element 11 may be a red light emitting element, the second light emitting element 12 may be a green light emitting element, and the third light emitting element 13 may be a blue light emitting element. Two light emitting elements may be mounted on each sub-pixel.

The first optical layer 141 may cover the plurality of light emitting elements 10 and bank patterns 130. Therefore, the first optical layer 141 may cover a space between the plurality of light emitting elements 10 and a space between the bank patterns 130. The first optical layers 141 may extend in the first direction X and may be spaced apart from each other in the second direction Y to be separated between pixel rows.

The first optical layer 141 may include an organic insulating material in which fine metal particles, such as titanium dioxide particles, are dispersed. Light emitted from the plurality of light emitting elements 10 may be scattered by the fine metal particles dispersed in the first optical layer 141 and emitted to the outside.

The second electrode 170 may be disposed on the plurality of light emitting elements 10. The second electrode 170 may be commonly connected to a plurality of pixels PXL. The second electrode 170 may be a thin electrode that transmits light. The second electrode 170 may be a transparent electrode material, such as indium tin oxide (ITO), but is not necessarily limited thereto.

The second electrode 170 may extend in the first direction (X-axis direction) and may be spaced apart from each other in the second direction (Y-axis direction). The second electrode 170 may include a first area 171 disposed on an upper surface of the light emitting element 10 and an upper surface of the first optical layer 141, a second area 172 in contact with the contact electrode 163 and electrically connected to the contact electrode 163, and a third area 173 disposed on a side surface of the first optical layer 141 and connecting the first area 171 with the second area 172.

In a plan view, the plurality of second electrodes 170 may each overlap the first optical layer 141, and the second area 172 may cover an outer flat surface of the first optical layer 141.

The second optical layer 142 may be an organic insulating material surrounding the periphery of the first optical layer 141. The second optical layer 142 may be disposed on the insulating layer 122 together with the first optical layer 141. The first optical layer 141 and the second optical layer 142 may include the same material (e.g., siloxane). For example, the first optical layer 141 may be siloxane containing titanium oxide (TiOₓ), and the second optical layer 142 may be siloxane not containing titanium oxide (TiOₓ). However, the present disclosure is not necessarily limited thereto, and the first optical layer 141 and the second optical layer 142 may be made of the same material or different materials.

According to the embodiment, since the second area 172 of the second electrode 170 is entirely formed flat and is connected to the contact electrode 163, stress is not concentrated excessively at a point at which the second area 172 is connected to the contact electrode 163. Therefore, it is possible to effectively prevent cracks from occurring in the second electrode 170.

The second optical layer 142 may cover the second area 172 and the third area 173 of the second electrode 170. An upper surface of the second optical layer 142 and an upper surface of the first area 171 of the second electrode 170 may be disposed on the same surface. In other words, the first optical layer 141 and the second optical layer 142 may serve as planarization layers. Therefore, since there is no step on a surface on which a black matrix 190 is formed, patterns of the black matrix 190 may be easily formed on the first optical layer 141 and the second optical layer 142. However, the present disclosure is not necessarily limited thereto, and the upper surfaces of the second optical layer 142 and the second electrode 170 may have different heights.

The black matrix 190 may be an organic insulating material to which black pigment is added. The second electrode 170 may be in contact with the contact electrode 163 under the black matrix 190. A transmission hole 191 through which light emitted from the light emitting element 10 is emitted to the outside may be formed between the patterns of the black matrix 190. The black matrix 190 may solve a mixing problem of light emitted from neighboring light emitting elements 10 by the first optical layer 141.

A cover layer 180 may be an organic insulating material for covering the black matrix 190 and the second electrode 170. In FIG. 3, the configuration of the black matrix 190 and the cover layer 180 is omitted.

The contact electrode 163 may be electrically connected to the first connection line RT1 disposed thereunder, and the first connection line RT1 may be connected to the pixel driving circuit 20. Therefore, the cathode voltage may be applied to the second electrode 170 through the contact electrode 163. The first electrode 161 may be electrically connected to the second connection line RT2. This will be described below.

Referring to FIG. 5, the contact electrode 163 and the signal lines TL1 to TL6 may be disposed on the same surface. The pixel driving circuit 20 may be disposed under the contact electrode 163 and the signal lines TL1 to TL6. When the pixel driving circuit 20 is a driving driver, a plurality of driving drivers may be disposed in the display panel.

A passivation layer 133 may expose the contact electrode 160 to electrically connect the contact electrode 163 and the second electrode 170. In addition, the passivation layer 133 may insulate the signal lines TL2 to TL5 and the second electrode 170.

Referring to FIG. 6, a connection portion 161a of the first electrode 161 may extend to one side surface 131 of the bank pattern 130 and may be electrically connected to the connection line RT2 disposed on the insulating layer 122.

The first electrode 161, the connection portion 161a, the signal line TL, and/or the connection lines RT1 and RT2 may include a single or multilayered metal layer formed of materials selected from titanium (Ti), molybdenum (Mo), and aluminum (Al). The first electrode 161, the connection portion 161a, the signal line TL, and/or the connection lines RT1 and RT2 may be in a multilayered structure including a first layer ML1, a second layer ML2, a third layer ML3, and a fourth layer ML4.

The first layer ML1 and the third layer ML3 may include titanium (Ti) or molybdenum (Mo). The second layer ML2 may include aluminum (Al). The fourth layer ML4 may include a transparent conductive oxide layer, such as ITO or indium zinc oxide (IZO), which has high adhesion to the solder pattern 162 and also has corrosion and acid resistance.

The first layer ML1, the second layer ML2, the third layer ML3, and the fourth layer ML4 may be sequentially deposited and then patterned by performing a photolithography process and an etching process.

The passivation layer 133 may include an opening hole 133a disposed on the first electrode 161 and the signal line TL and exposing the solder pattern 162.

The light emitting element 10 may include a first conductive semiconductor layer 10-1, an active layer 10-2 disposed on the first conductive semiconductor layer 10-1, and a second conductive semiconductor layer 10-3 disposed on the active layer 10-2. The first driving electrode 15 may be disposed under the first conductive semiconductor layer 10-1, and the second driving electrode 14 may be disposed on the second conductive semiconductor layer 10-3.

The light emitting element 10 may be formed on a silicon wafer using a metal organic chemical vapor deposition (MOCVD) method, a CVD method, a plasma-enhanced CVD (PECVD) method, a molecular beam epitaxy (MBE) method, a hydride vapor phase epitaxy (HVPE) method, a sputtering method, or the like.

The first conductive semiconductor layer 10-1 may be implemented using a compound semiconductor, such as group III-V or group II-VI, and doped with a first dopant. The first conductive semiconductor layer 10-1 may be made of any one or more of a semiconductor material with a composition formula of Alₓ₁In_{y1}Ga_{(1-x1-y1)}N (0≤x1≤1, 0≤y1≤1, 0≤x1+y1≤1), AlGaAs, GaP, GaAs, GaAsP, and AlGaInP, but is not limited thereto. When the first dopant is an n-type dopant, such as Si, Ge, Sn, Se, or Te, the first conductive semiconductor layer 10-1 may be an n-type nitride semiconductor layer. However, when the first dopant is a p-type dopant, the first conductive semiconductor layer 10-1 may be a p-type nitride semiconductor layer.

The active layer 10-2 is a layer in which electrons (or holes) implanted through the first conductive semiconductor layer 10-1 meet holes (or electrons) implanted through the second conductive semiconductor layer 10-3. The active layer 10-2 may be transitioned to a low energy level as electrons and holes recombine and generate light having the corresponding wavelength.

The active layer 10-2 may have any one of a single well structure, a multi-well structure, a single quantum well structure, a multi quantum well (MQW) structure, a quantum dot structure, or a quantum line structure, and the structure of the active layer 10-2 is not limited thereto. The active layer 10-2 may generate light in the visible ray wavelength band. As an example, the active layer 10-2 may output light in any one of blue, green, and red wavelength bands.

The second conductive semiconductor layer 10-3 may be disposed on the active layer 10-2. The second conductive semiconductor layer 10-3 may be implemented using a compound semiconductor, such as group III-V or group II-VI, and the second conductive semiconductor layer 10-3 may be doped with a second dopant. The second conductive semiconductor layer 10-3 may be made of any one or more of a semiconductor material with a composition formula of Alₓ₂In_{y2}Ga_{(1-x2-y2)}N (0≤x2≤1, 0≤y2≤1, 0≤x2+y2≤1), AlGaAs, GaP, GaAs, GaAsP, and AlGaInP, but is not limited thereto. When the second dopant is a p-type dopant, such as Mg, Zn, Ca, Sr, or Ba, the second conductive semiconductor layer 10-3 doped with the second dopant may be a p-type semiconductor layer. When the second dopant is an n-type dopant, the second conductive semiconductor layer 10-3 may be an n-type nitride semiconductor layer.

A reflective layer 16 may be disposed on side surfaces and a lower surface of the light emitting element 10. The reflective layer 16 may have a structure in which a reflective material is dispersed in a resin layer, but is not necessarily limited thereto. As an example, the reflective layer 16 may be formed as a reflector with any of various structures. Light emitted from the active layer 10-2 is reflected upward by the reflective layer 16, thereby increasing light extraction efficiency.

Although it has been described in the embodiment that the light emitting element 10 has a vertical structure in which driving electrodes 14 and 15 are disposed above and under the light emitting structure, the light emitting element 10 may have a lateral structure or a flip chip structure other than the vertical structure,.

Referring to FIG. 7, the main light emitting element 12a and the sub light emitting element 12b of the sub-pixel may be disposed on the bank pattern 130. An example of the second light emitting element 12 will be described. The 1-1 electrode 161-1 connected to the main light emitting element 12a may extend to one side surface of the bank pattern 130 and may be electrically connected to the 2-1 connection line RT21 disposed thereunder. The 1-2 electrode 161-1 connected to the sub light emitting element 12b may extend to the other side surface of the bank pattern 130 and may be electrically connected to the 2-2 connection line RT22 disposed thereunder.

The pixel driving circuit 20 may apply the anode voltage to the main light emitting element 12a through the 2-1 connection line RT21 and apply the anode voltage to the sub light emitting element 12b through the 2-2 connection line RT22. The pixel driving circuit 20 may apply the cathode voltage to the main light emitting element 12a and the sub light emitting element 12b through the first connection line RT1 and the second electrode 170.

The pixel driving circuit 20 may adjust brightness by driving only the main light emitting element 12a and adjust brightness by simultaneously driving the main light emitting element 12a and the sub light emitting element 12b. When the main light emitting element 12a becomes a dark spot, brightness may be adjusted by driving only the sub light emitting element 12b.

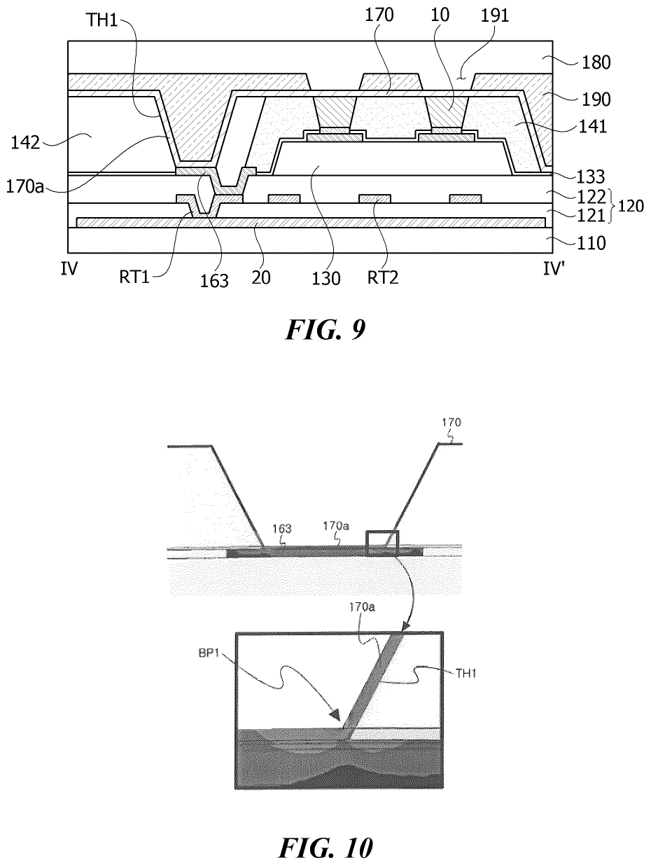

FIG. 8 is a view showing a display device according to another embodiment of the present specification. FIG. 9 is a cross-sectional view along line IV-IV in FIG. 8. FIG. 10 is a view showing a state in which stress is concentrated on a second electrode disposed in a through-hole.

Referring to FIGS. 8 and 9, the second electrode 170 may be electrically connected to the contact electrode 163 through a contact hole TH1 formed in the second optical layer 142. The second optical layer 142 may include the contact hole TH1 that exposes the contact electrode 163. The second electrode 170 may be inserted into the contact hole TH1 of the second optical layer 142 and may be in contact with an upper surface of the contact electrode 163. The contact hole TH1 may be formed in an outer area of the pixel.

Referring to FIG. 10, since the second electrode 170 is relatively thin and the contact hole TH1 is formed greater than the thickness of the second electrode 170, a stress concentration area BP1 may occur on a portion 170a of the second electrode 170 formed on side surface portions of the contact hole TH1. Therefore, there is a risk of cracks occurring in the portion 170a of the second electrode 170 formed near the contact hole TH1.

However, when the second electrode 170 in a flat and extended state is connected to the contact electrode 163 instead of forming the contact hole TH1 as described above in FIG. 4, it is possible to prevent stress from being excessively applied to the second electrode 170. Therefore, it is possible to prevent the occurrence of cracks in the second electrode.

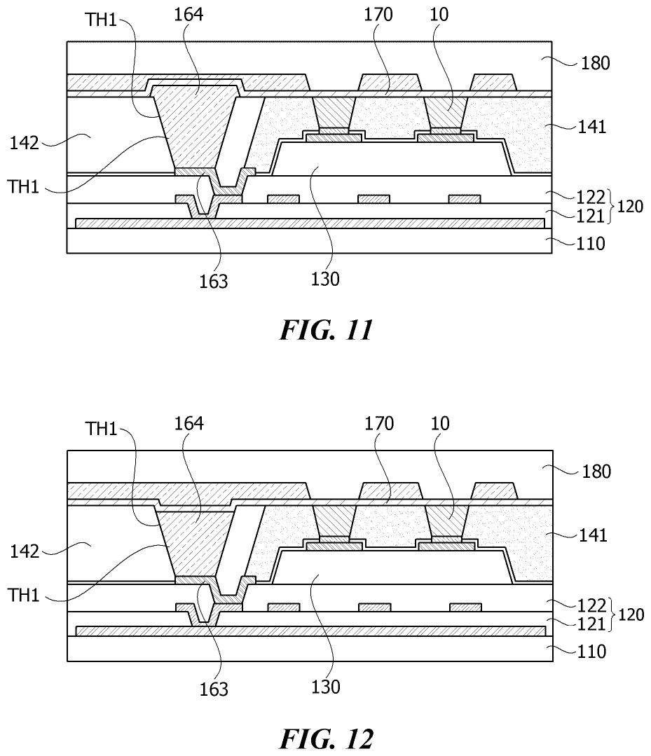

FIG. 11 is a view showing a first modified example of the display device of FIG. 8. FIG. 12 is a view showing a second modified example of the display device of FIG. 8.

Referring to FIG. 11, the contact hole TH1 may be filled with a separate through electrode 164. The through electrode 164 may include various conductive materials that may fill the contact hole TH1. Since the second electrode 170 is disposed on the through electrode 164, the second electrode 170 may be formed relatively flat, thereby preventing the occurrence of excessive stress.

Referring to FIG. 12, the contact hole TH1 may be filled with the through electrode 164 only up to a selected height rather than fully filled with the through electrode 164. With this structure, a depth of the second electrode 170 inserted into the contact hole TH1 may be relatively low. Therefore, it is possible to reduce a step of the second electrode 170, thereby reducing the probability of the occurrence of cracks.

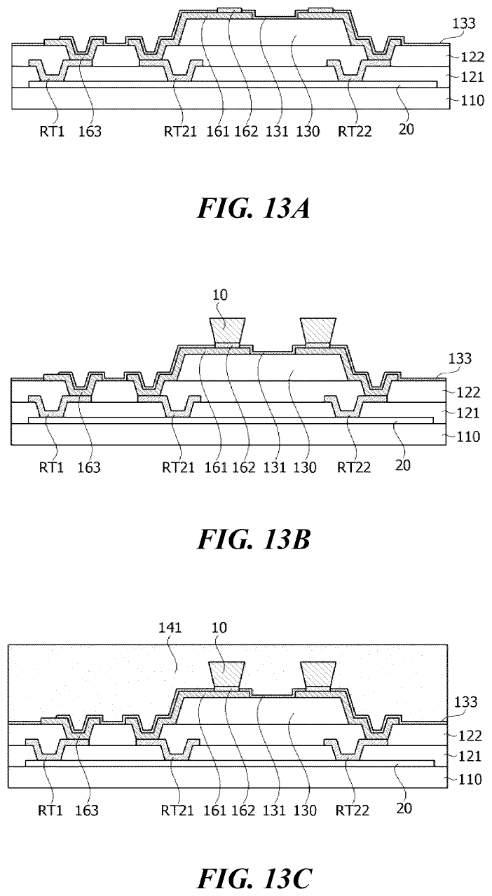

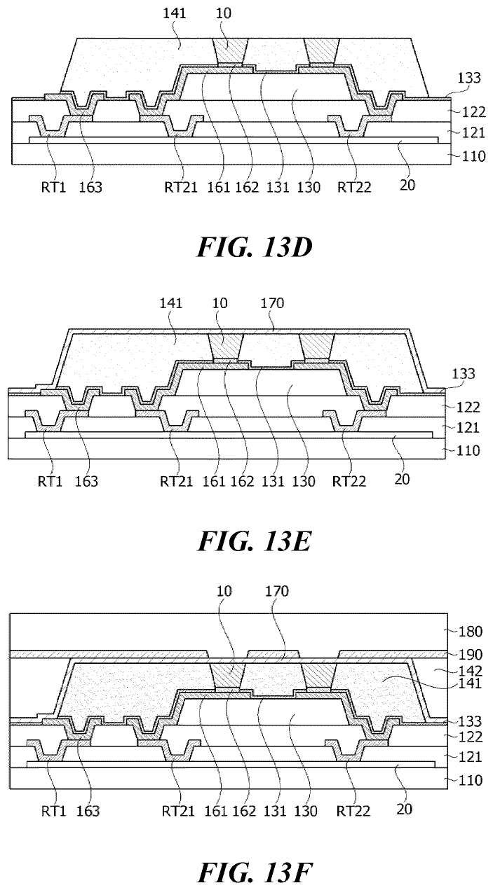

FIGS. 13A to 13F are views showing a method of manufacturing the display device according to one embodiment of the present specification.

Referring to FIG. 13A, the pixel driving circuit 20 may be formed on the substrate 110, and the buffer layer 121 may be formed on the pixel driving circuit 20. The pixel driving circuit may drive a plurality of pixels by receiving the driving voltage, the image signals (digital signals), the synchronization signals synchronized with the image signals, and the like and outputting the anode voltage and the cathode voltage of the light emitting element 10. The pixel driving circuit 20 may be disposed in the non-display area NA and disposed under the display area AA.

Thereafter, the connection lines RT1 and RT2 may be formed on the buffer layer 121, and then the insulating layer 122 may be formed. The connection lines RT1 and RT2 may pass through the buffer layer 121 and may be electrically connected to the pixel driving circuit 20. To drive each pixel, the number of connection lines RT1 and RT2 and a stack count may be changed in any of various ways. Therefore, the stack count of the connection lines RT1 and RT2 and the insulating layer 122 may be two or more.

The bank pattern 130 may be formed on the insulating layer 122 to select a transfer position of the light emitting element 10. The bank pattern 130 may be made of an organic insulating material, such as photosensitive photo acryl or photosensitive polyimide, but is not limited thereto. The bank pattern 130 may guide an attachment position of the light emitting element 10 in the transfer process of the light emitting element 10. However, the bank pattern 130 may be omitted.

An electrode material may be applied on the insulating layer 122 and the bank pattern 130 and then patterned to form a plurality of first electrodes 161 and the contact electrodes 163. The plurality of first electrodes 161 are areas on which the light emitting element 10 is disposed, and the contact electrode 163 is an area to which the second electrode 170 is electrically connected. Thereafter, the passivation layer 133 may be formed in the electrode areas excluding the area on which the plurality of first electrodes 161 and the contact electrode 163 are formed.

The solder pattern 162 may be disposed on the first electrode 161. The solder pattern 162 may be made of indium (In), tin (Sn), or an alloy thereof, but is not limited thereto.

Referring to FIG. 13B, a plurality of light emitting elements 10 may each be transferred onto the solder pattern 162. One pixel may include light emitting elements 10 of three colors. The first light emitting element may be a red light emitting element, the second light emitting element may be a green light emitting element, and the third light emitting element may be a blue light emitting element. Two light emitting elements may be mounted on each sub-pixel.

The transfer method is not particularly limited. In other words, the light emitting element 10 grown on the semiconductor growth substrate may be primarily transferred to the transfer substrate and then secondarily transferred to the panel substrate, or the light emitting element 10 grown on the semiconductor growth substrate may be directly transferred to the panel substrate.

Referring to FIGS. 13C and 13D, the first optical layer 141 may be formed on the entirety of the substrate 110 and then patterned to expose the upper surface of the light emitting element 10 and the contact electrode 163. The portions of the first optical layer 141 excluding an area sufficient to cover the light emitting element 10 and the bank pattern 130 may be removed. Therefore, the first optical layer 141 may cover a space between the plurality of light emitting elements 10 and a space between the bank patterns 130. In this case, the upper surface of the light emitting element 10 may be exposed upward from the first optical layer 141.

The first optical layer 141 may include an organic insulating material in which fine metal particles, such as titanium dioxide particles, are dispersed. Light emitted from the light emitting elements 10 may be scattered by the fine metal particles dispersed in the first optical layer 141 and emitted to the outside.

Referring to FIG. 13E, the second electrode 170 may be formed on the plurality of light emitting elements 10. The second electrode 170 may be commonly connected to a plurality of pixels PXL. The second electrode 170 may be a thin metal electrode through which light is transmitted. The second electrode 170 may be a transparent electrode material, such as ITO, but is not necessarily limited thereto.

The second electrode 170 may be divided to be disposed in each row through patterning. The plurality of divided second electrodes 170 may be electrically connected to the contact electrode 163.

Referring to FIG. 13F, the second optical layer 142 may be formed to surround the periphery of the first optical layer 141. In this process, the second optical layer 142 may cover a portion of the second electrode 170 connected to the contact electrode 163.

The second optical layer 142 may be disposed on the insulating layer 122 together with the first optical layer 141. The first optical layer 141 and the second optical layer 142 may include the same material (e.g., siloxane). For example, the first optical layer 141 may be siloxane containing titanium oxide (TiOₓ), and the second optical layer 142 may be siloxane not containing titanium oxide (TiOₓ).

Thereafter, the black matrix 190 may be formed on the second electrode 170 and the second optical layer 142, and the cover layer 180 may be formed on the black matrix 190.

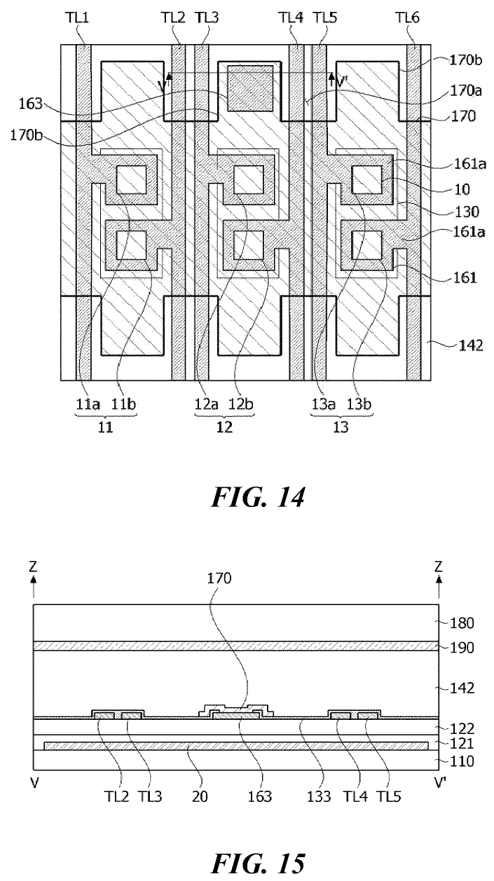

FIG. 14 is a view showing a modified example of the second electrode. FIG. 15 is a cross-sectional view along line V-V′ in FIG. 14.

Referring to FIG. 14, a portion of the second electrode 170 may be removed not to overlap the signal line TL in a plan view so that one or more concave portions 170a and one or more convex portions 170b are formed alternately. Any one of the convex portions 170b may be connected to the contact electrode 163. In addition, the plurality of concave portions 170a and the plurality of convex portions 170b may be formed alternately. Any one of the convex portions 170b may be connected to the contact electrode 163. Although FIG. 14 shows an embodiment in which the plurality of convex portions 170b are formed and one of the convex portions 170b is connected to the contact electrode 163, the convex portions 170b excluding the convex portion 170b connected to the contact electrode 163 may be formed selectively.

Referring to FIG. 15, since only the passivation layer 133 with a small thickness is disposed between the signal line TL and the second electrode 170 and a capacitance is formed higher than those of other areas, there is a problem that interference occurs in the driving signal. Referring to FIGS. 14 and 15, in the case of removing a portion of the second electrode 170 overlapping the signal line TL in the second area 172 disposed outside the first optical layer 141, it is possible to reduce a parasitic capacitance between the second electrode 170 and the signal line TL. In addition, the second electrode 170 may be formed in a portion of the second area 172 in which no signal line TL is formed, thereby increasing an area of the second electrode 170 to reduce a resistance.

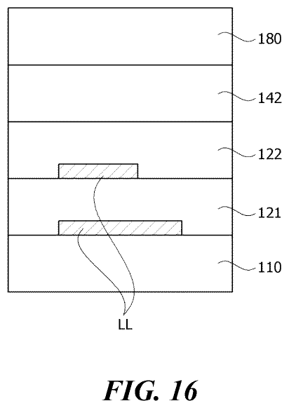

FIG. 16 is a cross-sectional view along line VI-VI′ in FIG. 1.

Referring to FIGS. 1 and 16, a plurality of signal lines LL may be disposed on the buffer layer 121 and the insulating layer 122 in the non-display area NA. Data driving signals, gate driving signals, or control signals for controlling driving operations of the driving circuits may be supplied to the plurality of signal lines LL. The non-display area NA may include an edge area EA adjacent to an edge of the panel substrate. The edge area EA is directly exposed to moisture, heat, etc. When the organic layers, such as the buffer layer 121 and the insulating layer 122 included in the panel substrate, and the metal layers, such as the plurality of signal lines LL disposed in the non-display area NA, are exposed to moisture and heat, there may be phenomena of cracks occurring in the organic layers or metal layer delamination.

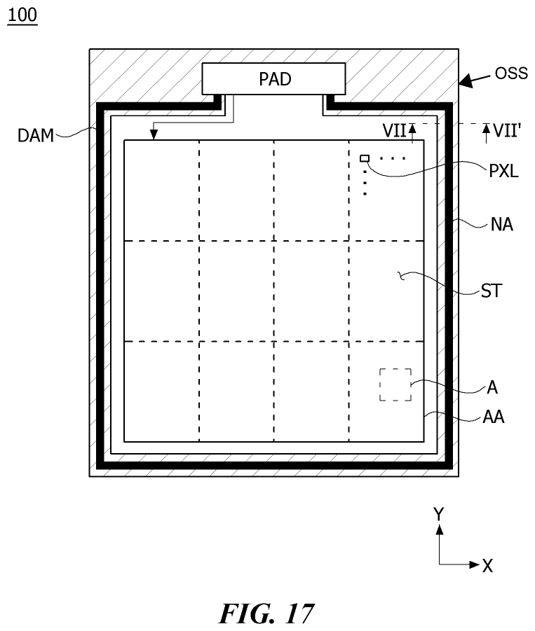

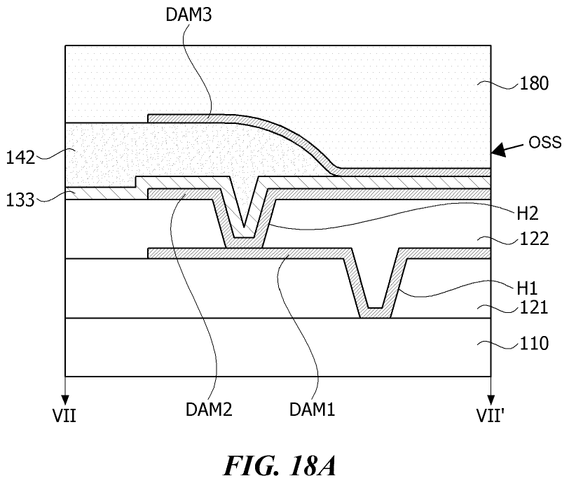

FIG. 17 is a plan view of the display device according to one embodiment of the present disclosure.

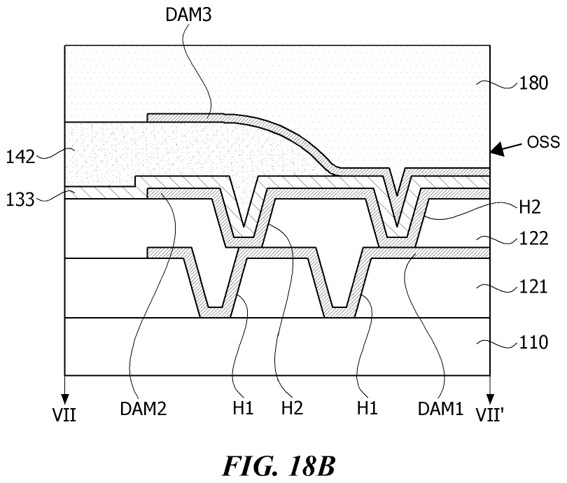

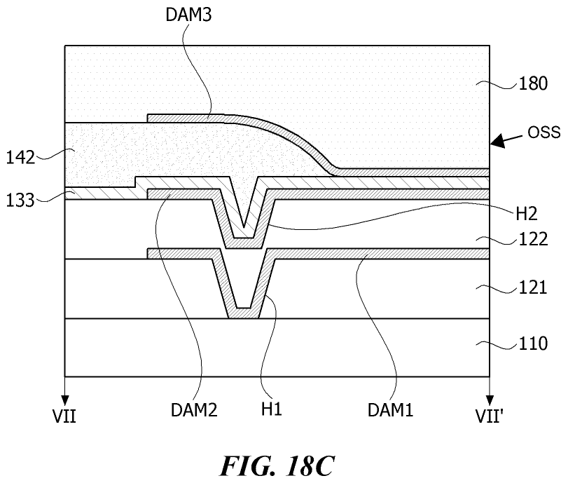

FIGS. 18A, 18B, and 18C are cross-sectional views along line VII-VII′ in FIG. 17.

Referring to one embodiment of the present disclosure according to FIGS. 17 and 18A, a metal dam DAM may be disposed in the non-display area NA to surround the signal lines disposed in the non-display area NA.

The metal dam DAM may be disposed to surround at least three surfaces of the display area AA, but is not limited thereto. The metal dam DAM may be formed through the following process. At least one first hole H1 may be formed in the buffer layer 121 disposed in the edge area EA.

A first metal dam DAM1 may be formed on the buffer layer 121 to cover the first hole H1. The insulating layer 122 may be disposed to cover the buffer layer 121 and a first metal dam DAM1. At least one second hole H2 formed by removing the insulating layer 122 may be formed on the first metal dam DAM1. A second metal dam DAM2 may be formed on the insulating layer 122 to cover the second hole H2. The passivation layer 133 may be disposed to cover the second metal dam DAM2 and the second hole H2. The passivation layer 133 may be formed to cover only a portion of the second metal dam DAM2. The second optical layer 142 may be disposed on the passivation layer 133. The second optical layer 142 may be formed in contact with a portion of the second metal dam DAM2. A height of the second optical layer 142 may gradually decrease toward the edge area EA in the edge area EA. A third metal dam DAM3 may be disposed to cover the second optical layer 142. The third metal dam DAM3 may be formed to be directly connected to the second metal dam DAM2. At least a portion of the second optical layer 142 may be in contact with the second metal dam DAM2 and the third metal dam DAM3 at the same time. The cover layer 180 may be disposed on the third metal dam DAM3. The first hole H1 and the second hole H2 may not overlap each other. The holes H1 and H2 may be disposed in a zigzag shape. Although not shown in the drawings, the display area AA and the non-display area NA may further include at least one organic layer on the buffer layer 121, and at least one metal layer may be further included on each organic layer. Each of the organic layer and metal layer may include a hole and a metal dam formed in the same manner as the first and second holes H1 and H2 or the first and second metal dams DAM1 and DAM2 that are included in one embodiment of FIGS. 17 and 18A.

FIG. 18B shows the display device according to one embodiment of the present disclosure.

At least one first hole H1 may be formed in the buffer layer 121 disposed in the edge area EA. The first metal dam DAM1 may be formed on the buffer layer 121 to cover the first hole H1. The insulating layer 122 may be disposed to cover the buffer layer 121 and the first metal dam DAM1. At least one second hole H2 formed by removing the insulating layer 122 may be formed on the first metal dam DAM1. A portion of at least one of the second holes H2 may overlap at least one of the first holes H1. The second metal dam DAM2 may be formed on the insulating layer 122 to cover the second hole H2. The passivation layer 133 may be disposed to cover the second metal dam DAM2 and the second hole H2. The passivation layer 133 may be formed to cover only a portion of the second metal dam DAM2. The second optical layer 142 may be disposed on the passivation layer 133. The second optical layer 142 may be formed in contact with a portion of the second metal dam DAM2. The height of the second optical layer 142 may gradually decrease toward the edge area EA in the edge area EA. The third metal dam DAM3 may be disposed to cover the second optical layer 142. The third metal dam DAM3 may be formed to be directly connected to the second metal dam DAM2. At least a portion of the second optical layer 142 may be in contact with the second metal dam DAM2 and the third metal dam DAM3 at the same time. Although not shown in the drawings, the display area AA and the non-display area NA may further include at least one organic layer on the buffer layer 121, and at least one metal layer may be further included on each organic layer. Each of the organic layer and metal layer may include a hole and a metal dam formed in the same manner as the first and second holes H1 and H2 or the first and second metal dams DAM1 and DAM2 that are included in one embodiment of FIGS. 17 and 18B.

FIG. 18C shows the display device according to one embodiment of the present disclosure.

At least one first hole H1 may be formed in the buffer layer 121 disposed in the edge area EA. The first metal dam DAM1 may be formed on the buffer layer 121 to cover the first hole H1. The insulating layer 122 may be disposed to cover the buffer layer 121 and the first metal dam DAM1. At least one second hole H2 formed by removing the insulating layer 122 may be formed on the first metal dam DAM1. The entire hole area of at least one of the second holes H2 may overlap at least one of the first holes H1. The second metal dam DAM2 may be formed on the insulating layer 122 to cover the second hole H2. The passivation layer 133 may be disposed to cover the second metal dam DAM2 and the second hole H2. The passivation layer 133 may be formed to cover only a portion of the second metal dam DAM2. The second optical layer 142 may be disposed on the passivation layer 133. The second optical layer 142 may be formed in contact with a portion of the second metal dam DAM2. The height of the second optical layer 142 may gradually decrease toward the edge area EA in the edge area EA. The third metal dam DAM3 may be disposed to cover the second optical layer 142. The third metal dam DAM3 may be formed to be directly connected to the second metal dam DAM2. At least a portion of the second optical layer 142 may be in contact with the second metal dam DAM2 and the third metal dam DAM3 at the same time. Although not shown in the drawings, the display area AA and the non-display area NA may further include at least one organic layer on the buffer layer 121, and at least one metal layer may be further included on each organic layer. Each organic layer and metal layer may include a hole and a metal dam formed in the same manner as the first and second holes H1 and H2 or the first and second metal dams DAM1 and DAM2 that are included in one embodiment of FIGS. 17 and 18C.

When the first to third metal dams DAM1, DAM2, and DAM3 are disposed as described with reference to FIGS. 18A, 18B, and 18C, by blocking a path along which substance that causes the degradation of reliability of the display panel, such as moisture, permeates the display panel, it is possible to protect components vulnerable to moisture, such as the light emitting element 10 and the pixel driving circuit 20 disposed on the display panel. In addition, the path along which cracks caused by moisture or heat expand can be blocked by the plurality of metal dams DAM1, DAM2, and DAM3. In some embodiments, the first to third metal dams DAM1, DAM2, and DAM3 may be disposed to be spaced at a selected distance D from the edge of the display panel. The edge of the display panel may also be referred to as an outermost side surface OSS of the display panel. This is because when the plurality of metal dams DAM1, DAM2, and DAM3 are exposed to air at the edge of the display panel, the metal dams DAM1, DAM2, and DAM3 may corrode, causing the permeation of moisture. When the metal dam DAM is formed as shown in FIG. 18A, it is possible to reduce an area of the metal dam DAM, thereby implementing a display device with a thin bezel. In the embodiment of FIG. 18B, when a plurality of holes are formed in each organic layer, it is possible to increase the path along which moisture permeates, and thus moisture is difficult to permeate the display panel. When the metal dam DAM is disposed to overlap the holes disposed in each organic layer as in the embodiment of FIG. 18C, it is possible to reduce the area of the metal dam DAM, thereby implementing the display device with a thin bezel.

The display device according to the embodiment of the present specification may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a laptop computer, a monitor, a camera, a camcorder, a home appliance, etc. In addition, the display device according to one or more embodiments of the present specification may be applied to an organic light emitting lighting device or an inorganic light emitting lighting device.

Since the contents of the specification described in the above-described technical problem, technical solution, and advantageous effects do not specify the essential features of the claims, the scope of the claims is not limited by the items described in the contents of the specification.

According to the present specification, it is possible to reduce a parasitic capacitance generated in an overlapping area of a cathode and a signal line and reduce an increase in resistance of the cathode, thereby enabling low-power driving.

Display devices according to various embodiments of the present disclosure may be described as follows.

A display device according to one embodiment of the present disclosure may comprise a display panel including a display area and a non-display area surrounding the display area, and a metal dam disposed in the non-display area to surround at least three surfaces of the display panel, wherein the display panel includes a substrate, a pixel driving circuit disposed on the substrate, and a light emitting element driven by the pixel driving circuit.

According to one embodiment of the present disclosure, the metal dam may be spaced a selected distance from an edge of the display panel.

According to one embodiment of the present disclosure, the metal dam may be formed of a plurality of metal layers connected through at least one hole.

According to one embodiment of the present disclosure, the metal dam may include a first metal dam, a second metal dam, and a third metal dam that are disposed in the non-display area while surrounding the at least three surfaces of the display area.

According to one embodiment of the present disclosure, the display panel may further include the substrate, a buffer layer disposed on the substrate, a first hole formed in the buffer layer in the non-display area, an insulating layer on the buffer layer, a second hole formed in the insulating layer in the non-display area, a passivation layer formed to cover the second hole, a first optical layer formed to cover the passivation layer, the first metal dam disposed in the non-display area while surrounding the at least three surfaces of the display area on the buffer layer, the second metal dam overlapping the first metal dam on the insulating layer in a plan view, and the third metal dam overlapping the first metal dam on the first optical layer in a plan view, and the first metal dam and the second metal dam are connected through the first hole.

According to one embodiment of the present disclosure, the first hole and the second hole may be disposed to overlap each other.

According to one embodiment of the present disclosure, the first hole and the second hole may be disposed not to overlap each other.

According to one embodiment of the present disclosure, the second metal dam and the third metal dam may be partially connected.

According to one embodiment of the present disclosure, the passivation layer may be disposed between an outermost portion of the second metal dam and an outermost portion of the third metal dam.

The effects of the present specification are not limited to the above-described effects, and other effects that are not mentioned will be able to be clearly understood by those skilled in the art from the above detailed description.

Although embodiments of the present disclosure have been described in more detail with reference to the accompanying drawings, the present disclosure is not necessarily limited to the embodiments, and various modifications may be carried out without departing from the technical spirit of the present disclosure. Therefore, the embodiments disclosed in the present disclosure are not intended to limit the technical spirit of the present disclosure, but intended to describe the same, and the scope of the technical spirit of the present disclosure is not limited by these embodiments. Therefore, it should be understood that the above-described embodiments are illustrative and not restrictive in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including a display area and a non-display area adjacent to the display area, the display panel having at least three surfaces; and
a metal dam disposed in the non-display area to surround the at least three surfaces of the display panel,
wherein the display panel includes:
a substrate;
a pixel driving circuit disposed on the substrate; and
a light emitting element driven by the pixel driving circuit.

2. The display device of claim 1, wherein the metal dam is spaced at a selected distance from an edge of the display panel.

3. The display device of claim 1, wherein the metal dam is formed of a plurality of metal layers coupled through at least one hole.

4. The display device of claim 1, wherein the metal dam includes a first metal dam, a second metal dam, and a third metal dam that are disposed in the non-display area while surrounding the at least three surfaces of the display area.

5. The display device of claim 4, wherein the display panel further includes:
a buffer layer disposed on the substrate;
a first hole in the buffer layer in the non-display area;
an insulating layer on the buffer layer;
a second hole in the insulating layer in the non-display area;
a passivation layer covering the second hole;
a first optical layer covering the passivation layer;
wherein the first metal dam is disposed in the non-display area while surrounding the at least three surfaces of the display area on the buffer layer;
wherein the second metal dam overlaps the first metal dam on the insulating layer in a plan view; and
wherein the third metal dam overlaps the first metal dam on the first optical layer in a plan view, and
wherein the first metal dam and the second metal dam are coupled through the first hole.

6. The display device of claim 5, wherein the first hole and the second hole are disposed to overlap each other.

7. The display device of claim 6, wherein the first hole and the second hole are disposed not to overlap each other.

8. The display device of claim 6, wherein the second metal dam and the third metal dam are partially coupled.

9. The display device of claim 6, wherein the passivation layer is disposed between an outermost portion of the second metal dam and an outermost portion of the third metal dam.

10. The display device of claim 2, wherein the edge of the display panel indicative of an outermost side surface of the display panel.
